(19) United States
(12) Patent Application Publication
(10) Pub. No.: US 2003/0039892 A1
(43) Pub. Date: Feb. 27, 2003

(54) Method of optical proximity correction

(75) Inventors: Chang-Jyh Hsieh, Hsin-Chu (TW); Pen-Li Lin, Taipei (TW); Ming-Jui Chen, Hsin-Chu (TW)

Correspondence Address: LOWE HAUPTMAN GILMAN & BERNER, LLP, 1700 Diagonal Road, Suite 310, Alexandria, VA, 22314, US

(73) Assignee: UNITED MICROELECTRONICS CORP.

(21) Appl. No.: 09/930,305

(22) Filed: Aug. 16, 2001

(51) Int. Cl. G03F 9/00

(52) U.S. Cl. 430/5; 430/322; 430/296; 430/942; 355/67; 355/77

(57) ABSTRACT

A method of optical proximity correction. The method at least includes the following steps. First of all, a transparent plate is provided, an opaque film is formed on the transparent plate, wherein the opaque film pattern is a polygon. Finally, at least a serif is added on a line-end of the polygon by using optical proximity correction, wherein the line-end does not include non-90 degree corner.

### BACKGROUND OF THE INVENTION

1. Field of the Invention

The present invention generally relates to lithography, and more particularly to a method of optical proximity correction.

2. Description of the Prior Art

The minimum feature sizes of integrated circuits (ICs) have been shrinking for years. Commensurate with this size reduction, various process limitations made IC fabrication more difficult. One area of fabrication technology in which such limitations has appeared is photolithography.

Photolithography involves selectively exposing regions of a resist coated silicon wafer to a radiation pattern, and then developing the exposed resist in order to selectively protect regions of wafer layer (e.g., regions of substrate, polysilicon, or dielectric).

An integral component of photolithographic apparatus is a “reticle” which includes a pattern corresponding to features at one layer in an IC design. Such reticle typically includes a transparent glass plate covered with a patterned light blocking material such as chromium. The reticle is placed between a radiation source producing radiation of a pre-selected wavelength and a focusing lens which may form part of a “stepper” apparatus. Placed beneath the stepper is a resist covered silicon wafer. When the radiation from the radiation source is directed onto the reticle, light passes through the glass (regions not having chromium patterns) and projects onto the resist covered silicon wafer. In this manner, an image of the reticle is transferred to the resist.

The resist (sometimes referred to as a “photoresist”) is provided as a thin layer of radiation-sensitive material that is spin-coated over the entire silicon wafer surface. The resist material is classified as either positive or negative depending on how it responds to light radiation. Positive resist, when exposed to radiation becomes more soluble and is thus more easily removed in a development process. As a result, a developed positive resist contains a resist pattern corresponding to the dark regions on the reticle. Negative resist, in contrast, becomes less soluble when exposed to radiation. Consequently, a developed negative resist contains a pattern corresponding to the transparent regions of the reticle. For simplicity, the following discussion will describe only positive resists, but it should be understood that negative resists might be substituted therefor.

To remedy “As light passes through the reticle, it is refracted and scattered by the chromium edges, this causes the projected image to exhibit some rounding and other optical distortion” this problem, a reticle correction technique known as optical proximity correction (“OPC”) has been developed. Optical proximity correction involves adding dark regions to and/or subtracting dark regions from a reticle design at locations chosen to overcome the distorting effects of diffraction and scattering. Typically, OPC is performed on a digital representation of a desired IC pattern. First, the digital distortion will result. Then the optical proximity correction is applied to compensate for the distortion. The resulting pattern is ultimately transferred to the reticle glass.

Referring to FIG.1, illustrates how optical proximity correction may be employed to modify the reticle design. As shown, a corrected reticle 100 includes two bas polygon features 104 and 104 outline in chromium on a glass plate 110. Various “corrections” have been added to these, base features. Some correction takes the form of “serifs” 102a-102f and 104a-104f, wherein the 102b, 102e, 104b, and 104e are non-90 degree corner corrections. The non-90 degree corner corrections increase data file size to save more computer aided design size for optical proximity correction. Serifs are small appendage-type addition or subtraction regions typically made at corner regions on reticle designs. In the example shown in FIG. 1, the serifs 102a, 102c, 102d, 102f 104a, 104c, 104d, and 104f are line-end chromium extensions protruding beyond the corners of base polygon 102 and 104. The serifs 102b, 102e, 104b, and 104e are non-90 degree corner pattern chromium extensions protruding beyond the corners of base polygon 102 and 104. These features have the intended effect of “sharpening” the corner of the illumination pattern on the wafer surface.

For 0.18 μm and below process, the OPC (optical proximity correction) technology is necessary to get better critical dimension (CD) control. However mask making and inspection becomes more and more difficult since the huge file size that is induced by generated OPC(optical proximity correction). For example, 50GB file size, it will spend about one day for mask writing and more than two days for mask inspection. Therefore, how to reduce the file size is an important issue for OPC (optical proximity correction). The traditional OPC methodology is corrected on line-width, line-end, in-corner and out-corner. But the final data file size of the OPC is depended on polygon.

For the forgoing reasons, there is a necessary method of optical proximity correction.

### SUMMARY OF THE INVENTION

In accordance with the present invention, a method of optical proximity correction that substantially can be used to increase lithography resolution in conventional process.

One object of the present invention is to provide a method of optical proximity correction to increase lithography resolution.

Another object of the present invention is to provide a method of optical proximity correction to reduce the optical proximity correction output file size.

One another object of the present invention is to provide a method of optical proximity correction to improve photolithography process window and critical dimension (CD) uniformity.

In order to achieve the above object, the present invention provides a method of optical proximity correction. The method at least includes the following steps. First of all, a transparent plate is provided, an opaque film is formed on the transparent plate, wherein the opaque film pattern is a polygon. Finally, at least a serif is added on a line-end of the polygon by using optical proximity correction, wherein the line-end does not include non-90 degree corner.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1 shows conventional optical proximity correction reticle in the prior art;

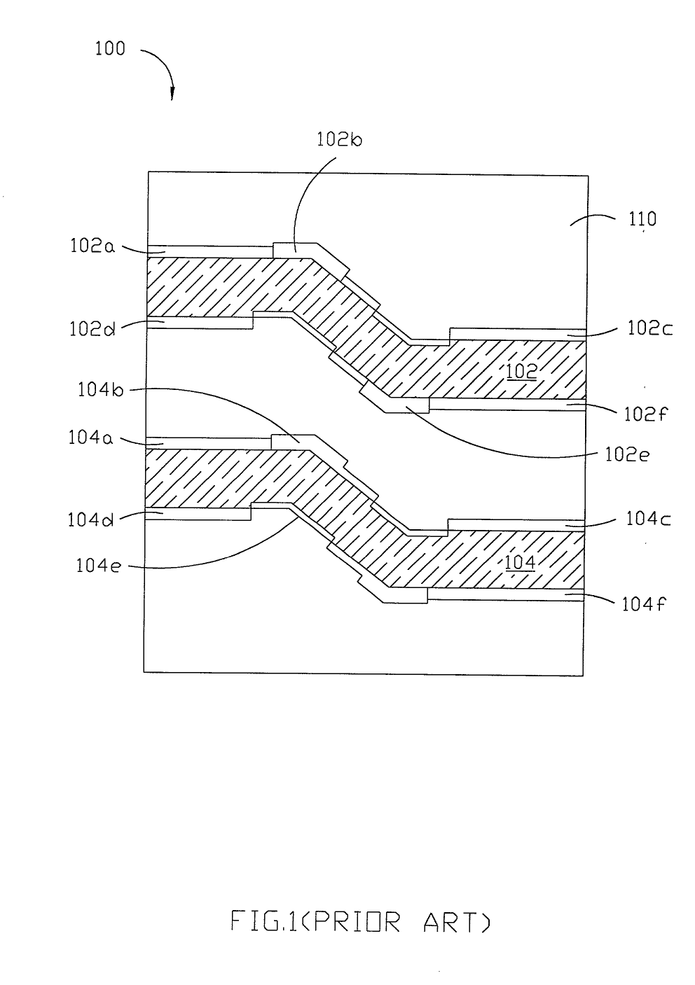

FIG.2 is cross-sectional view of a method of optical proximity correction in accordance with one preferred embodiment of the present invention.

### DESCRIPTION OF THE PREFERRED EMBODIMENT

The semiconductor devices of the present invention are applicable to a broad range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarity of illustration and should not be interpreted in a limiting sense. Accordingly, these regions will have dimensions, including length, width and depth, when fabricated in an actual device.

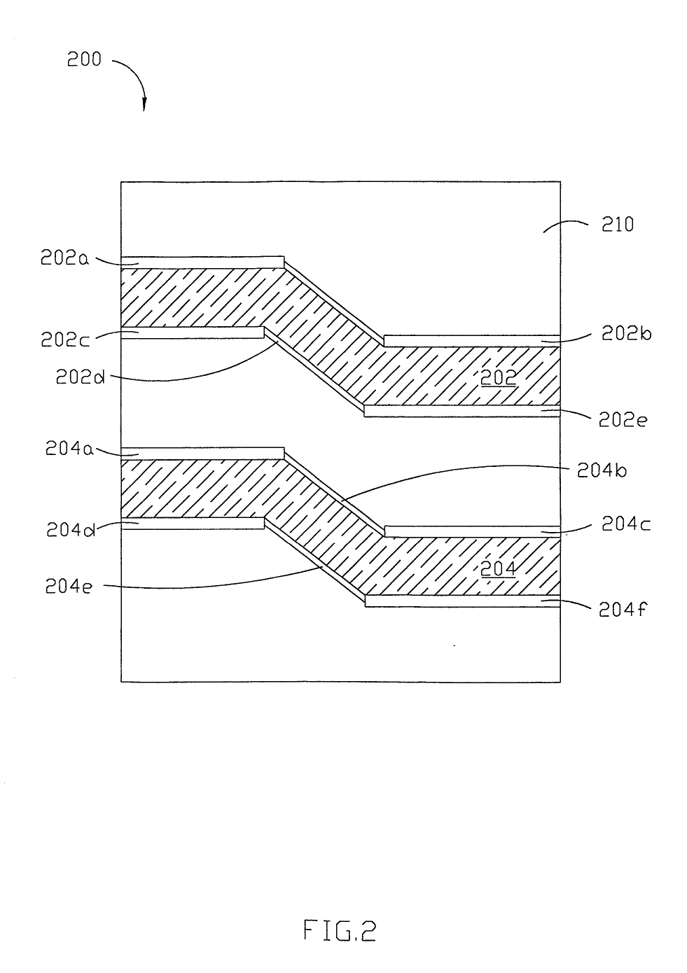

FIG. 2 is cross-sectional view of a method of optical proximity correction in accordance with one preferred embodiment of the present invention.

Referring to FIG. 2 illustrates how optical proximity correction (OPC) may be employed to modify the reticle design. As shown, a corrected reticle 200 includes two bas polygon features 204 and 204 outline in chromium on a quartz plate 210. Various “corrections” have been added to these, base features. Some correction takes the form of “serifs” 202a-102e and 204a-204f. Serifs are small appendage-type addition or subtraction regions typically made at corner regions on reticle designs. This invention optical proximity correction methodology is corrected on line-end for polygon, but not corrected non-90 degree corner for polygon, wherein the non-90 degree corner is selected from the group consisting of 45-degree corner, 135-degree corner, 225-degree corner and 315-degree corner. Therefor, it reduced data file size without resulting in a bad pattern. In the example shown in FIG.2, the serifs are line-end chromium extensions protruding beyond the corners of base polygon 202 and 204. These features have the intend effect of “sharpening” the corner of the illumination pattern on the wafer surface. The experimental data shows: the original data file size is 11.2 MB, the traditional OPC data file size is 32.1 MB, and the invention OPC data file size is 25.9 MB for 0.15 μm optical proximity correction test run. According in the experimental data, the data file size was reduced by 15%-25% in this invention.

However, this invention optical proximity correction methodology is corrected on line-width, in-corner, out-corner, and line-end for reducing data file size by optical proximity correction. But, the non-90 degree includes 45-degree corner, 135-degree corner, 225-degree corner and 315-degree corner is only corrected line-end bias, but the others such as in-corner, out-corner is not corrected. It is not effect device performance and can reduce output tile time to save penetrate time, mask fabrication, and test time by optical proximity correction.

The method of optical proximity correction using the above explained method, has the following advantages:

1. The present invention is to provide a method of optical proximity correction to increase lithography resolution.

2. The present invention is to provide a method of optical proximity correction to reduce the optical proximity correction output file size.

3. The present invention is to provide a method of optical proximity correction to improve photolithography process window and critical dimension (CD) uniformity.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of optical proximity correction, said method comprising the steps of:
providing a transparent plate;
forming an opaque film on said transparent plate, wherein said opaque film pattern is a polygon; and
adding at least a serif on a line-end of said polygon by using optical proximity correction, wherein said line-end does not include non-90 degree corner.

2. The method according to claim 1, wherein said transparent plate comprises quartz.

3. The method according to claim 1, wherein said opaque film comprises chromium.

4. The method according to claim 1, wherein said opaque film is a line.

5. The method according to claim 1, wherein said non-90 degree corner is selected from the group consisting of 45-degree corner, 135-degree corner, 225-degree corner and 315-degree corner.

6. A method of optical proximity correction, said method comprising the steps of:
providing a transparent plate;
forming an opaque film on said transparent plate, wherein said opaque film pattern is selected from the group consisting of a polygon and a line; and
adding at least a serif on a line-end of said polygon by using optical proximity correction, wherein said line-end does not include non-90 degree corner.

7. The method according to claim 6, wherein said transparent plate comprises quartz.

8. The method according to claim 6, wherein said opaque film comprises chromium.

9. The method according to claim 6, wherein said non-90 degree corner is selected from the group consisting of 45-degree corner, 135-degree corner, 225-degree corner and 315-degree corner.

10. A method of optical proximity correction, said method comprising the steps of:
providing a transparent plate;
forming an opaque film on said transparent plate, wherein said opaque film pattern comprises a polygon of non-90 degree corner; and
adding at least a serif on a line-end of said polygon by using optical proximity correction, wherein said line-end does not include non-90-degree corner.

11. The method according to claim 10, wherein said transparent plate comprises quartz.

12. The method according to claim 10, wherein said opaque film comprises chromium.

13. The method according to claim 10, wherein said opaque film is a line.

14. The method according to claim 10, wherein said non-90 degree corner is selected from the group consisting of 45-degree corner, 135-degree corner, 225-degree corner and 315-degree corner.

15. A method of optical proximity correction, said method comprising the steps of:
providing a transparent plate;
forming an opaque film on said transparent plate, wherein said opaque film pattern comprises a polygon of non-90 degree corner and said non-90 degree corner is selected from the group consisting of 45-degree corner, 135-degree corner, 225-degree corner and 315-degree corner; and
adding at least a serif on a line-end of said polygon by using optical proximity correction, wherein said line-end does not include non-90-degree corner.

16. The method according to claim 15, wherein said transparent plate comprises quartz.

17. The method according to claim 15, wherein said opaque film comprises chromium.

18. The method according to claim 15, wherein said opaque film is a line.

19. A method of optical proximity correction, said method comprising the steps of:
providing a transparent quartz plate;
forming an opaque chromium film on said transparent quartz plate, wherein said opaque chromium film pattern comprises a polygon of non-90 degree corner and said non-90 degree corner is selected from the group consisting of 45-degree corner, 135-degree corner, 225-degree corner and 315-degree corner; and
adding at least a serif on a line-end of said polygon by using optical proximity correction, wherein said line-end does not include non-90 degree corner.

20. The method according to claim 10, wherein said opaque film is a line.
